(19) United States
(12) Patent Application Publication
(10) Pub. No.: US 2022/0369474 A1
(43) Pub. Date: Nov. 17, 2022

(54) CIRCUIT BOARD STRUCTURE AND METHOD OF MANUFACTURING THE SAME

(71) Applicant: HONG FU JIN PRECISION INDUSTRY (WuHan) CO., LTD., Wuhan (CN)

(72) Inventors: HOU-YUAN CHOU, New Taipei (TW); XIAO-CHU JIN, Wuhan (CN); SHI ZHANG, Wuhan (CN); BO WU, Shenzhen (CN); ZHI-HONG XU, Shenzhen (CN); MEI-WEN KAO, New Taipei (TW); YI-CHIH WU, New Taipei (TW)

(21) Appl. No.: 17/334,842

(22) Filed: May 31, 2021

(30) Foreign Application Priority Data
May 11, 2021 (CN) 202110513195.X

(51) Int. Cl. H05K 3/36; H05K 3/32; H05K 1/11

(52) U.S. Cl. CPC H05K 3/363; H05K 3/326; H05K 1/111; H05K 1/118; H05K 2201/09445; H05K 2201/042; H05K 2201/2036

(57) ABSTRACT

A circuit board structure includes a rigid circuit board, a flexible circuit board, a plurality of conductive bumps, and a plurality of spacers. The rigid and flexible circuit boards are stacked one above the other. The conductive bumps are formed between the rigid and flexible circuit boards. The spacers are formed between the rigid and flexible circuit boards and spaced apart from the conductive bumps.

### CROSS-REFERENCE TO RELATED APPLICATIONS

This application claims the benefit of China Patent Application No. 202110513195.X filed on May 11, 2021, which is hereby incorporated by reference herein and made a part of specification.

### BACKGROUND

A conventional rigid printed circuit board (PCB) includes a plurality of components, a plurality of signal lines connected to the components, and a plurality of metal lines connected between the signal lines on front and back thereof. As the number of the components increases, the routing of the signal lines becomes more difficult.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view illustrating a circuit board structure according to the first exemplary embodiment of the present disclosure.

FIG. 2 is a schematic plan view illustrating a first circuit board of the circuit board structure of FIG. 1 according to the first exemplary embodiment of the present disclosure.

FIG. 3 is a schematic plan view illustrating a second circuit board of the circuit board structure of FIG. 1 according to the first exemplary embodiment of the present disclosure.

FIGS. 4-11 are schematic cross-sectional views illustrating intermediate stages of manufacturing the circuit board structure of FIG. 1 according to some embodiments of the present disclosure.

FIG. 12 is a schematic cross-sectional view illustrating a circuit board structure according to the second exemplary embodiment of the present disclosure.

FIG. 13A is a schematic plan view illustrating a first circuit board of the circuit board structure of FIG. 12 according to the second exemplary embodiment of the present disclosure.

FIG. 13B is a schematic plan view illustrating a second circuit board of the circuit board structure of FIG. 12 according to the second exemplary embodiment of the present disclosure.

FIG. 14 is a schematic cross-sectional view illustrating a circuit board structure according to the third exemplary embodiment of the present disclosure.

FIG. 15A is a schematic plan view illustrating a first circuit board of the circuit board structure of FIG. 14 according to the third exemplary embodiment of the present disclosure.

FIG. 15B is a schematic plan view illustrating a second circuit board of the circuit board structure of FIG. 14 according to the third exemplary embodiment of the present disclosure.

FIG. 16 is a schematic cross-sectional view illustrating a circuit board structure according to the fourth exemplary embodiment of the present disclosure.

FIG. 17 is a schematic cross-sectional view illustrating a circuit board structure according to the fifth exemplary embodiment of the present disclosure.

FIG. 18 is a schematic cross-sectional view illustrating a circuit board structure according to the sixth exemplary embodiment of the present disclosure.

FIG. 19 is a flowchart illustrating a method of manufacturing a circuit board structure of FIG. 1 according to some embodiments of the present disclosure.

### DETAILED DESCRIPTION

Detailed descriptions of the present disclosure are illustrated below in conjunction with the accompanying drawings. However, it is to be understood that the descriptions and the accompanying drawings disclosed herein are merely illustrative and exemplary and not intended to limit the scope of the present disclosure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

It will be understood that the terms “and/or” and “at least one” include any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

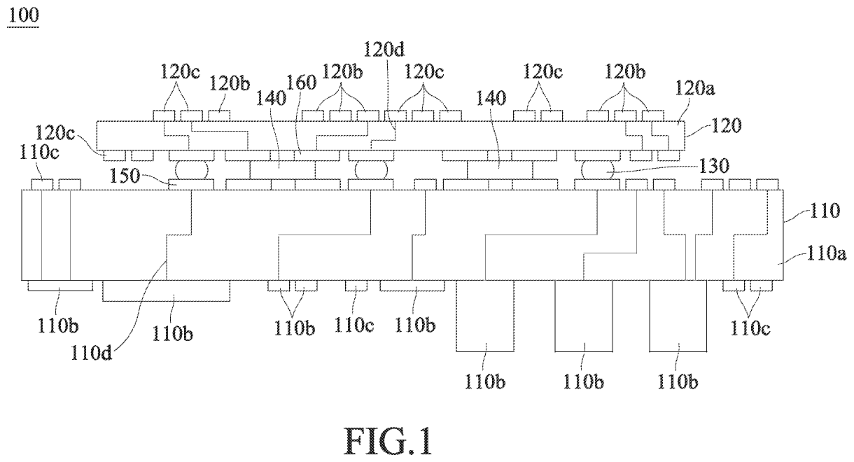

FIG. 1 is a schematic cross-sectional view illustrating a circuit board structure 100 according to the first exemplary embodiment of the present disclosure. As illustrated in FIG. 1, the circuit board structure 100 includes a first circuit board 110, a second circuit board 120, a plurality of conductive bumps 130 (only one of the conductive bumps 130 is labeled in FIG. 1), and a plurality of spacers 140. The first circuit board 110 is a rigid circuit board, e.g., a rigid printed circuit board (PCB), and is composed of one or more board layers 110a. As illustrated in FIG. 1, the first circuit board 110, e.g., a motherboard, includes a plurality of components 110b mounted on, i.e., soldered to, front and/or back of the board layer 110a, a plurality of signal lines 110c formed on the front and/or back of the board layer 110a and connected to one or more of the components 110b, an electrical ground (not shown) formed on the front and/or back of the board layer 110a and connected to one or more of the components 110b, and a plurality of metal lines 110d (only one of the metal lines 110d is labeled in FIG. 1) formed in the board layer 110a and connected between the signal lines 110c on the front and back of the board layer 110a and/or between the electrical ground on the front and back of the board layer 110a.

The board layer 110a includes a rigid substrate that is not easily deformable, such as a glass fabric epoxy resin substrate, a glass fabric bismaleimide triazine resin substrate, a glass fabric polyphenylene ether resin substrate, an aramid nonwoven fabric-epoxy resin substrate, aramid nonwoven fabric-polyimide resin substrate, or any suitable rigid substrates. For example, the board layer 110a has a thickness from about 20 um to about 600 um.

The components 110b may include surface-mount devices (SMDs), e.g., integrated circuits (ICs), active and passive devices (such as resistors, capacitors, inductors, diodes, and transistors), sockets, switches, connectors, and the like. The signal lines 110c and/or the electrical ground may be formed by etching a copper foil attached to the board layer 110a.

A plurality of conductive pads 150 (only one of the conductive pads 150 is labeled in FIG. 1) may be formed as portions of the signal lines 110c and/or the electrical ground. The metal lines 110d, e.g., vias, may include via holes formed in the board layer 110a and filled with a conductive material, e.g., copper, tungsten, aluminum, tin, silver, gold, an alloy thereof, and various types of solders.

In this exemplary embodiment, the second circuit board 120 is stacked over the back of the first circuit board 110 and interconnects the signal lines 110c on the back of the first circuit board 110, reducing difficulty of routing signal lines of the first circuit board 110. In an alternative embodiment, the second circuit board 120 may be stacked over the front of the first circuit board 110 and interconnects the signal lines 110c on the front of the first circuit board 110.

The second circuit board 120, e.g., a daughterboard, is a flexible circuit board, e.g., a flexible PCB, and is composed of one or more film layers 120a. As illustrated in FIG. 1, the second circuit board 120 includes a plurality of signal lines 120c formed on the front and/or back of the film layer 120a, an electrical ground (not shown) formed on the front and/or back of the film layer 120a, and a plurality of metal lines 120d (only one of the metal lines 120d is labeled in FIG. 1) formed in the film layer 120a and connected between the signal lines 120c on the front and back of the film layer 120a and/or between the electrical ground on the front and back of the film layer 120a. In certain embodiments, the second circuit board 120 further includes a plurality of components 120b, e.g., at least one of which is an SMD, mounted on, i.e., soldered to, front and/or back of the film layer 120a and connected to one or more of the signal lines 120c and/or the electrical ground.

The film layer 120a includes a flexible substrate that is not as rigid as the rigid substrate of the board layer 110 and that is easily deformable. In various embodiments, the flexible substrate of the film layer 120 is a plastic substrate, such as a glass epoxy substrate and a glass polyimide substrate, a metallic substrate, such as an aluminum substrate and an iron substrate, a film substrate, such as a polyimide substrate and a polyethylene film substrate, or any suitable flexible substrates. For example, the film layer 120a has a thickness from about 10 um to about 100 um.

The components 120b may include ICs, active and passive devices (such as resistors, capacitors, inductors, diodes, and transistors), sockets, switches, connectors, and the like. The signal lines 120c and/or the electrical ground may be formed by etching a copper foil attached to the film layer 120a.

It is noted herein that, in some embodiments, the signal lines 110c, 120c are a data bus configured to transmit/receive data from one component 110b, 120b to another. In other embodiments, the signal lines 110c, 120c may be a control bus, an address bus, any type of bus, or a combination thereof.

A plurality of conductive pads 160 (only one of the conductive pads 160 is labeled in FIG. 1) may be formed as portions of the signal lines 120c and/or the electrical ground. The metal lines 120d, e.g., vias, may include via holes formed in the film layer 120a and filled with a conductive material, e.g., copper, tungsten, aluminum, tin, silver, gold, an alloy thereof, and various types of solders.

Each of the conductive bumps 130, e.g., solder bumps, solder lumps, or solder balls, is connected between a respective one of the conductive pads 150 of the first circuit board 120 and a respective one of the conductive pads 160 of the second circuit board 120. Examples of materials for the conductive bumps 130 include, but are not limited to, an alloy of tin and lead, an alloy of tin and antimony, an alloy of tin and silver, an alloy of tin, silver, and copper, an alloy of tin and zinc, an alloy of tin, silver, indium, and copper, and various types of solders.

As will be described further below, the spacers 140 serves to prevent occurrence of a short circuit between adjacent conductive bumps 130 during manufacturing of the circuit board structure 100. As illustrated in FIG. 1, the spacers 140 are mounted on, i.e., soldered to, the conductive pads 160 of the second circuit board 120, and abut, i.e., not soldered to, the conductive pads 150 of the first circuit board 110. In some embodiments, the spacers 140 are mounted on, i.e., soldered to, the conductive pads 160 of the second circuit board 120, and abut, i.e., not soldered to, the signal lines 110c and/or the electrical ground of the first circuit board 110. In other embodiments, the spacers 140 are mounted on, i.e., soldered to, the conductive pads 160 of the second circuit board 120, and abut the rigid substrate of the board layer 110a of the first circuit board 110.

The spacers 140 are spaced apart from the conductive bumps 130 and have a different material than the conductive bumps 130. For example, at least one of the spacers 140 is in the form of an SMD. In some embodiments, each of the spacers 140 has two or more terminals connected, i.e., soldered, to the conductive pads 160 of the signal lines 120c of the second circuit board 120. In other embodiments, each of the spacers 140 has two or more terminals connected, i.e., soldered, to the conductive pads 160 of the electrical ground of the second circuit board 120. For example, at least one of the spacers 140 is a resistor, such as a 0201 resistor.

It should be understood that, after reading this disclosure, other types of spacers 140 are contemplated as being within the scope of the present disclosure so long as its intended function is achieved and/or may be mounted on the second circuit board 120 using a surface-mount technology (SMT).

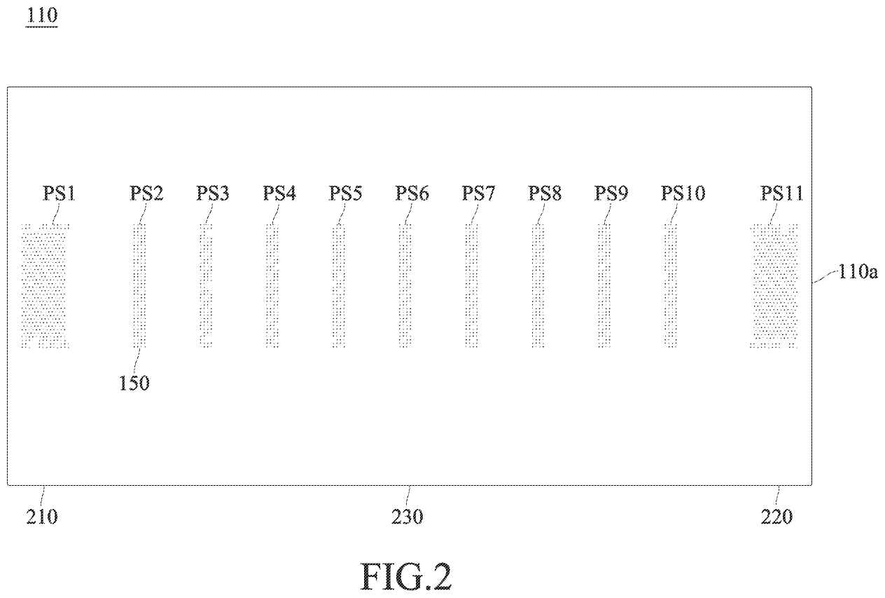

FIG. 2 is a schematic plan view illustrating the first circuit board 110 of the circuit board structure 100 according to the first exemplary embodiment of the present disclosure. As illustrated in FIG. 2, the conductive pads 150 (only one of the conductive pads 150 is labeled in FIG. 2) are divided into a plurality of pad sets (PS1-PS11) arranged along the length of the board layer 110a. In this exemplary embodiment, the pad sets (PS1, PS11) are at opposite end portions 210, 220 of the board layer 110a. The pad sets (PS2-PS10) are at a middle portion 230 of the board layer 110a between the end portions 210, 220 of the board layer 110a. The conductive pads 150 in the pad sets (PS1, PS11) define first and second areas, respectively. In some embodiments, the first and second areas have a substantially the same size and/or shape. For example, as illustrated in FIG. 2, the first and second areas have a generally rectangular shape. In other embodiments, the first and second areas have different sizes and/or shapes.

The conductive pads 150 in the pad sets (PS2-PS10) define a third area smaller than at least one of the first and second areas. In some embodiments, the third areas have a substantially the same size and/or shape. For example, as illustrated in FIG. 2, the third areas have a generally rectangular shape. In other embodiments, at least two of the third areas have different sizes and/or shapes.

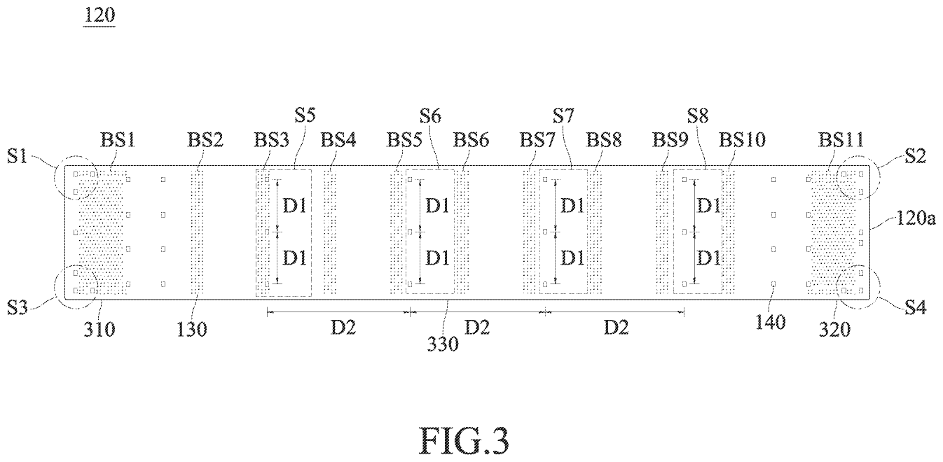

FIG. 3 is a schematic plan view illustrating the second circuit board 120 of the circuit board structure 100 according to the first exemplary embodiment of the present disclosure. In this exemplary embodiment, the film layer 120a has a smaller size than the board layer 110a of the first circuit board 110 and is generally rectangular in shape. In an alternative embodiment, the film layer 120a may have other polygonal shape, a circular shape, an elliptical shape, or any suitable shape.

As illustrated in FIG. 3, the conductive bumps 130 (only one of the conductive bumps 130 is labeled in FIG. 3) are divided into a plurality of bump sets (BS1-BS11) arranged along the length of the film layer 120a. In this exemplary embodiment, the bump sets (BS1, BS11) are at opposite end portions 310, 320 of the film layer 120a. The bump sets (BS2-BS10) are at a middle portion 330 of the film layer 120a between the end portions 310, 320 of the film layer 120a. The conductive bumps 130 in the bump sets (BS1, BS11) define fourth and fifth areas, respectively. In some embodiments, the fourth and fifth areas have a substantially the same size and/or shape. For example, as illustrated in FIG. 3, the fourth and fifth areas have a generally rectangular shape. In other embodiments, the fourth and fifth areas have different sizes and/or shapes.

The conductive bumps 130 in the bump sets (BS2-BS10) define a sixth area smaller than at least one of the fourth and fifth areas. In some embodiments, the sixth areas have a substantially the same size and/or shape. For example, as illustrated in FIG. 3, the third areas have a generally rectangular shape. In other embodiments, at least two of the sixth areas have different sizes and/or shapes.

In this exemplary embodiment, the second circuit board 120 is stacked over the back of the first circuit board 110 and interconnects the signal lines 110c on the back of the first circuit board 110, reducing difficulty of routing signal lines of the first circuit board 110. For example, the conductive bumps 130 in the bump sets (BS1, BS11), i.e., the conductive bumps 130 at the end portions 310, 320 of the film layer 120a, are connected to the conductive pads 150 on the back of the board layer 110a. In an alternative embodiment, the second circuit board 120 is stacked over the front of the first circuit board 110. In such an alternative embodiment, the conductive bumps 130 in the bump sets (BS1, BS11), i.e., the conductive bumps 130 at the end portions 310, 320 of the film layer 120a, are connected to the conductive pads 150 on the front of the board layer 110a.

It is noted that the layout of the spacers 140 (only one of the spacers 140 is labeled in FIG. 3) on the film layer 120a facilitates prevention of short circuit occurring between the conductive bumps 130 during manufacturing of the circuit board structure 100 of the present disclosure. For example, as illustrated in FIG. 3, three or more spacers 140, e.g., the spacers 140 enclosed by S1, S2, S3, or S4, may be disposed adjacent a corner of the film layer 120a.

One or more of the spacers 140, e.g., the spacers 140 enclosed by S5, may be disposed in one or more of the bump areas, e.g., the bump area defined by the conductive bumps 130 in the bump set (BS3).

The spacers 140 at the end portions 310, 320 of the film layer 120a may surround the conductive bumps 130 in the bump sets (BS1, BS11), respectively. The spacers 140 between the end portions 310, 320 of the film layer 120a, e.g., the spacers 140 enclosed by S5, S6, S7, and S8, may be arranged in an array of rows and columns. In certain embodiments, distances (D1) between adjacent pairs of the spacers 140 in a column may be substantially equal. Distances (D2) between adjacent pairs of the spacers 140 in a row may be substantially equal. In some embodiments, the distance (D1) may be smaller than the distance (D2). In other embodiments, the distance (D1) may be substantially equal to or larger than the distance (D2).

It should be understood that, after reading this disclosure, other layouts of spacers 140 are contemplated as being within the scope of the present disclosure so long as occurrence of a short circuit between the conductive bumps 130 is prevented during the manufacturing the circuit board structure 100 of the present disclosure.

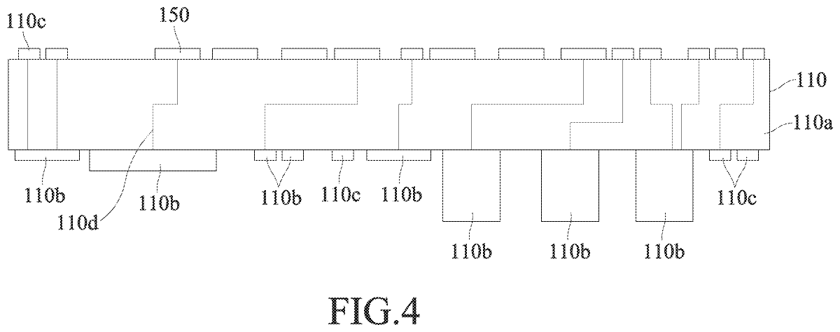

FIGS. 4-11 are schematic cross-sectional views illustrating intermediate stages of manufacturing the circuit board structure 100 according to some embodiments of the present disclosure. As illustrated in FIG. 4, a first circuit board 110 is provided. The first circuit board 110 is a rigid circuit board, e.g., a rigid PCB, and is composed of one or more board layers 110a.

The first circuit board 110 includes a plurality of components 110b, e.g., at least one of which is an SMD, mounted on, i.e., soldered to, front and/or back of the board layer 110a, a plurality of signal lines 110c formed on the front and/or back of the board layer 110a and connected to one or more of the components 110b, an electrical ground (not shown) formed on the front and/or back of the board layer 110a and connected to one or more of the components 110b, and a plurality of metal lines 110d (only one of the metal lines 110d is labeled in FIG. 4) formed in the board layer 110a and connected between the signal lines 110c on the front and back of the board layer 110a and/or between the electrical ground on the front and back of the board layer 110a.

The board layer 110a includes a rigid substrate that is not easily deformable, such as a glass fabric epoxy resin substrate, a glass fabric bismaleimide triazine resin substrate, a glass fabric polyphenylene ether resin substrate, an aramid nonwoven fabric-epoxy resin substrate, aramid nonwoven fabric-polyimide resin substrate, or any suitable rigid substrates. For example, the board layer 110a has a thickness from about 20 um to about 600 um.

The components 110b may include ICs, active and passive devices (such as resistors, capacitors, inductors, diodes, and transistors), sockets, switches, connectors, and the like. The signal lines 110c and/or the electrical ground may be formed by etching a copper foil attached to the board layer 110a.

A plurality of conductive pads 150 (only one of the conductive pads 150 is labeled in FIG. 4) may be formed as portions of the signal lines 110c and/or the electrical ground. The metal lines 110d, e.g., vias, may include via holes formed in the board layer 110a and filled with a conductive material, e.g., copper, tungsten, aluminum, tin, silver, gold, an alloy thereof, and various types of solders.

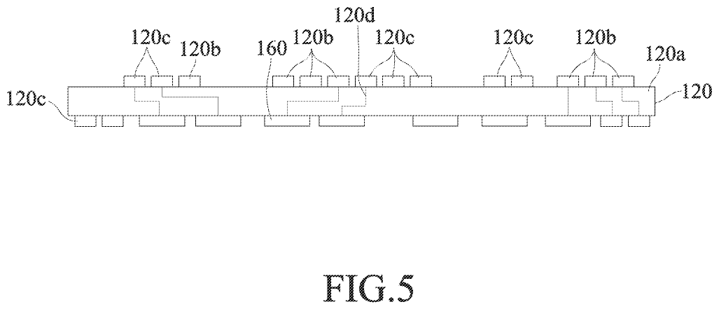

Next, as illustrated in FIG. 5, a second circuit board 120 is provided. The second circuit board 120 is a flexible circuit board, e.g., a flexible PCB, and is composed of one or more film layers 120a.

The second circuit board 120 includes a plurality of signal lines 120c formed on the front and/or back of the film layer 120a, an electrical ground (not shown) formed on the front and/or back of the film layer 120a, and a plurality of metal lines 120d (only one of the metal lines 120d is labeled in FIG. 5) formed in the film layer 120a and connected between the signal lines 120c on the front and back of the film layer 120a and/or between the electrical ground on the front and back of the film layer 120a. In certain embodiments, the second circuit board 120 further includes a plurality of components 120b, e.g., at least one of which is an SMD, mounted on front and/or back of the film layer 120a and connected to one or more of the signal lines 120c and/or the electrical ground.

The film layer 120a includes a flexible substrate that is not as rigid as the rigid substrate of the board layer 110 and that is easily deformable. In various embodiments, the flexible substrate of the film layer 120 is a plastic substrate, such as a glass epoxy substrate and a glass polyimide substrate, a metallic substrate, such as an aluminum substrate and an iron substrate, a film substrate, such as a polyimide substrate and a polyethylene film substrate, or any suitable flexible substrates. For example, the film layer 120a has a thickness from about 10 um to about 100 um.

The components 120b may include ICs, active and passive devices (such as resistors, capacitors, inductors, diodes, and transistors), sockets, switches, connectors, and the like. The signal lines 120c and/or the electrical ground may be formed by etching a copper foil attached to the film layer 120a.

It is noted herein that, in some embodiments, the signal lines 110c, 120c are a data bus configured to transmit/receive data from one component 110b, 120b to another. In other embodiments, the signal lines 110c, 120c may be a control bus, an address bus, any type of bus, or a combination thereof.

A plurality of conductive pads 160 (only one of the conductive pads 160 is labeled in FIG. 5) may be formed as portions of the signal lines 120c and/or the electrical ground. The metal lines 120d, e.g., vias, may include via holes formed in the film layer 120a and filled with a conductive material, e.g., copper, tungsten, aluminum, tin, silver, gold, an alloy thereof, and various types of solders.

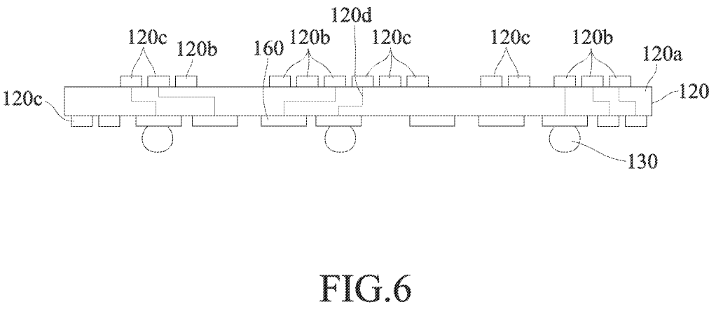

Next, as illustrated in FIG. 6, a plurality of conductive bumps 130 (only one of the conductive bumps 130 is labeled in FIG. 6), e.g., solder bumps, solder lumps, or solder balls, each of which is connected to a respective one of the conductive pads 160 of the second circuit board 120. Examples of materials for the conductive bumps 130 include, but are not limited to, an alloy of tin and lead, an alloy of tin and antimony, an alloy of tin and silver, an alloy of tin, silver, and copper, an alloy of tin and zinc, an alloy of tin, silver, indium, and copper, and various types of solders.

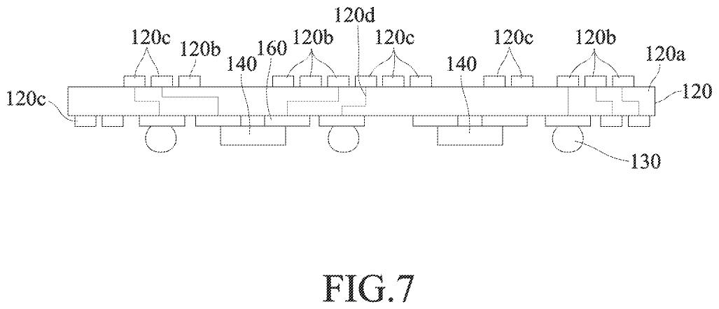

Next, as illustrated in FIG. 7, a plurality of spacers 140 are mounted on the conductive pads 160 of the second circuit board 120, such as by an SMT.

As will be described below, the spacers 140 serves to prevent occurrence of a short circuit between adjacent conductive bumps 130 during manufacturing of the circuit board structure 100. As illustrated in FIG. 7, the spacers 140 are mounted on, i.e., soldered to, the conductive pads 160 of the second circuit board 120.

The spacers 140 are spaced apart from the conductive bumps 130 and have a different material than the conductive bumps 130. For example, at least one of the spacers 140 is in the form of an SMD. In some embodiments, each of the spacers 140 has two or more terminals connected, i.e., soldered, to the conductive pads 160 of the signal lines 120c of the second circuit board 120. In other embodiments, each of the spacers 140 has two or more terminals connected, i.e., soldered, to the conductive pads 160 of the electrical ground of the second circuit board 120. For example, at least one of the spacers 140 is a resistor, such as a 0201 resistor.

It is noted herein that, because the spacers 140 are in the form of an SMD, e.g., a resistor, the spacers 140 are readily available off-the-shelf and are therefore cheaper and more convenient to implement.

It should be understood that, after reading this disclosure, other types of spacers 140 are contemplated as being within the scope of the present disclosure so long as its intended function is achieved and/or may be mounted on the second circuit board 120 using a surface-mount technology (SMT).

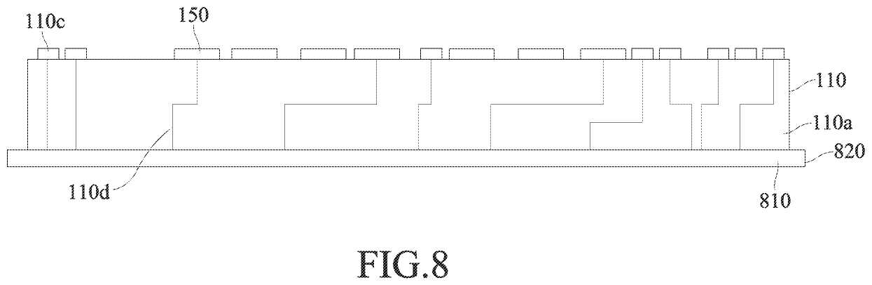

Next, as illustrated in FIG. 8, the first circuit board 110 is placed on a support member 810 of a fixture 820. Thereafter, a solder paste is coated on the conductive pads 150 of the first circuit board 150.

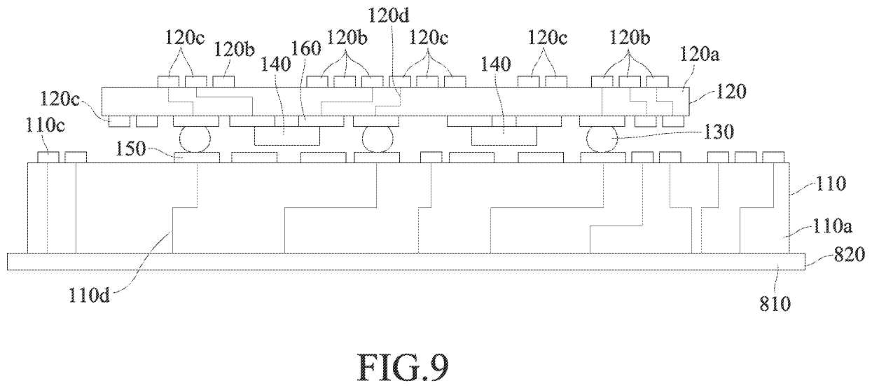

Next, as illustrated in FIG. 9, the second circuit board 120 is mounted on the first circuit board 110, such as by an SMT. Each of the conductive bumps 130 is connected to a respective one of the conductive pads 150 of the first circuit board 110.

In this exemplary embodiment, the second circuit board 120 is stacked over the back of the first circuit board 110 and interconnects the signal lines 110c on the back of the first circuit board 110, reducing difficulty of routing signal lines of the first circuit board 110. For example, the conductive bumps 130 at the opposite end portions of the film layer 120a are connected to the conductive pads 150 on the back of the board layer 110a. In an alternative embodiment, the second circuit board 120 is stacked over the front of the first circuit board 110. In such an alternative embodiment, the conductive bumps 130 at the end portions of the film layer 120a are connected to the conductive pads 150 on the front of the board layer 110a.

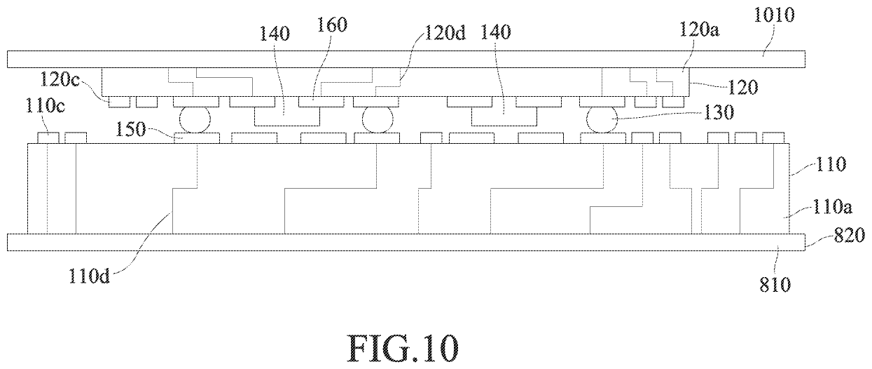

Next, as illustrated in FIG. 10, the second circuit board 120 is pressed against the first circuit board 110 with a pressure of, e.g., about 40 kg/cm², using a pressing member 1010 of the fixture 820.

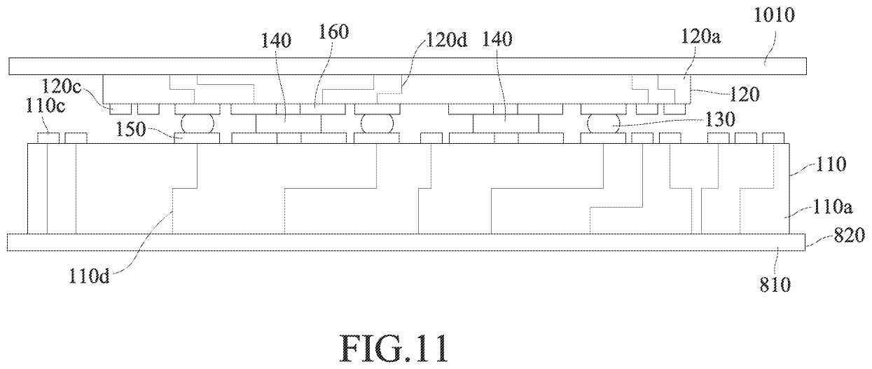

Next, as illustrated in FIG. 11, a reflow soldering process is performed on the first and second circuit boards 110, 120, resulting in the circuit board structure 100 of FIG. 1. As illustrated in FIG. 11, the spacers 140 abut, i.e., not soldered to, the conductive pads 150 of the first circuit board 110, thereby preventing occurrence of a short circuit between the conductive bumps 130. In some embodiments, the spacers 140 abut, i.e., not soldered to, the signal lines 110c and/or the electrical ground of the first circuit board 110. In other embodiments, the spacers 140 abut the rigid substrate of the board layer 110a of the first circuit board 110.

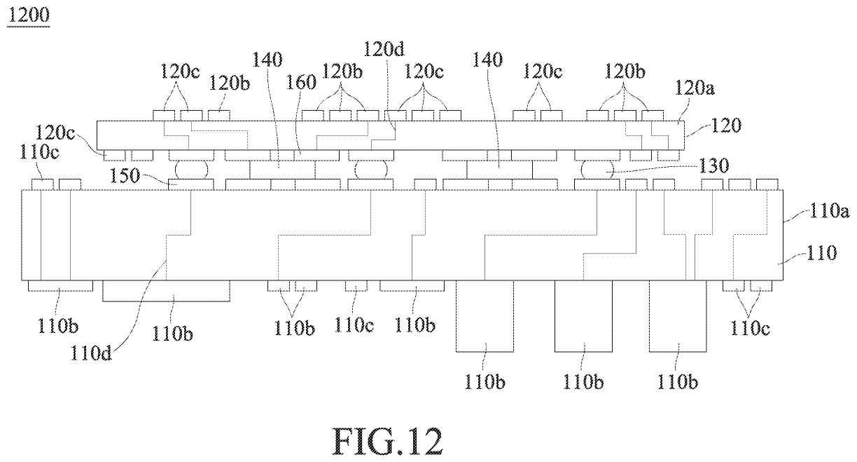

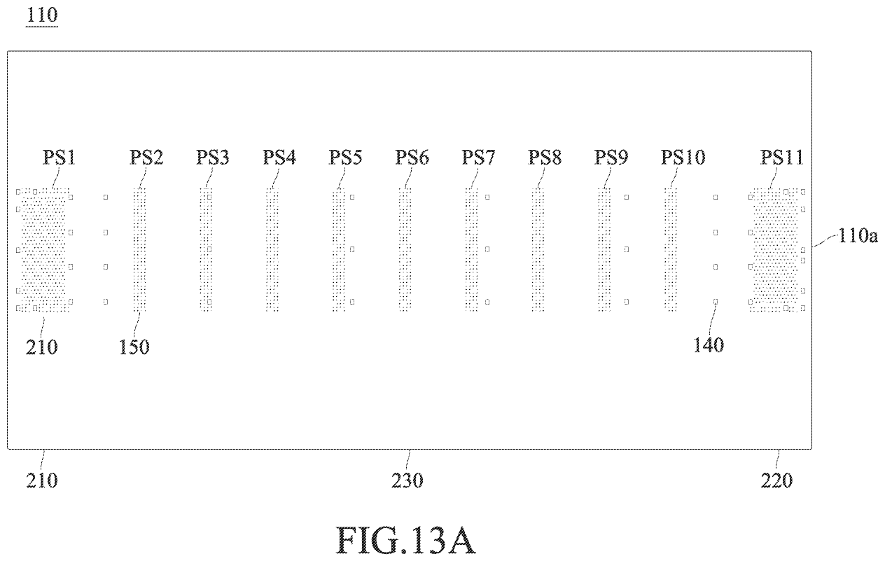

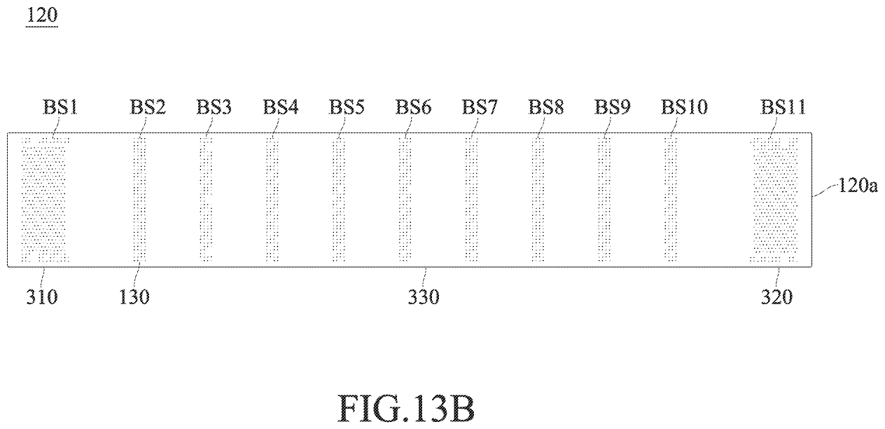

FIG. 12 is a schematic cross-sectional view illustrating a circuit board structure 1200 according to the second exemplary embodiment of the present disclosure. FIG. 13A is a schematic plan view illustrating a first circuit board 110 of the circuit board structure 1200 according to the second exemplary embodiment of the present disclosure. FIG. 13B is a schematic plan view illustrating a second circuit board 120 of the circuit board structure 1200 according to the second exemplary embodiment of the present disclosure. As illustrated in FIGS. 12 and 13A, the circuit board structure 1200 differs from the circuit board structure 100 in that the spacers 140 (only one of the spacers 140 is labeled in FIG. 13A) of the circuit board structure 1200 are mounted on, i.e., soldered to, the board layer 110a of the first circuit board 110 of the circuit board structure 1200. With further reference to FIG. 13B, the film layer 120a of the second circuit board 120 of the circuit board structure 1200 is dispensed with spacers.

As such, when the film layer 120a of the second circuit board 120 of the circuit board structure 1200 is mounted on the board layer 110a of the first circuit board 110 of the circuit board structure 1200, the spacers 140 abut, i.e., not soldered to, the conductive pads, e.g., conductive pads 160 of FIG. 1, the signal lines, e.g., signal lines 120c, the electrical ground, and/or the rigid substrate of the film layer 120a of the second circuit circuit 120 of the circuit board structure 1200.

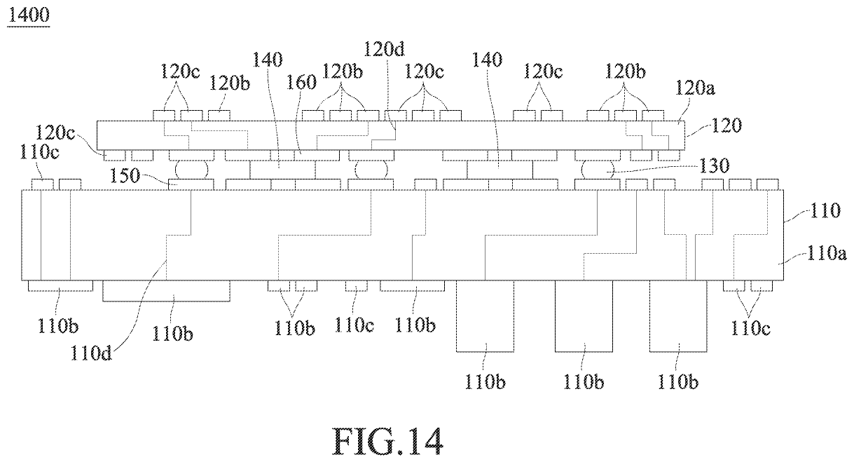

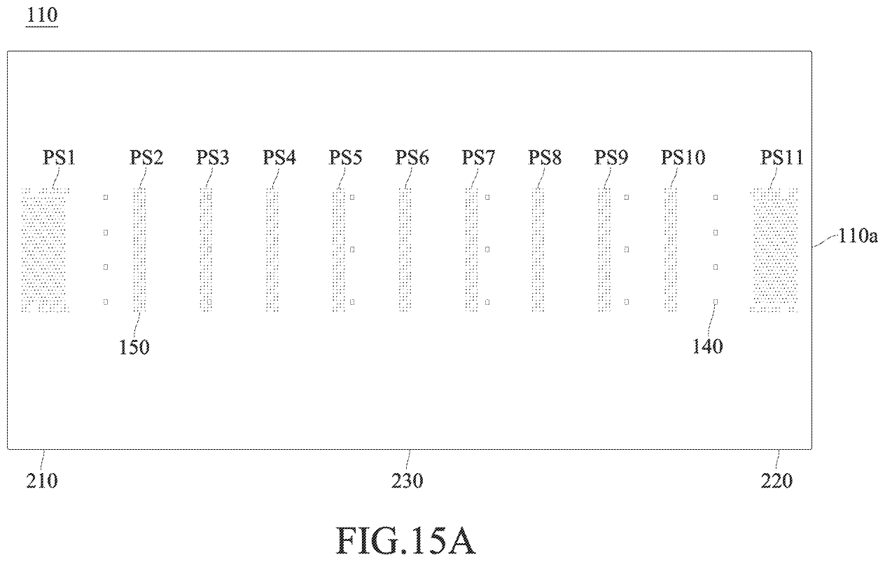

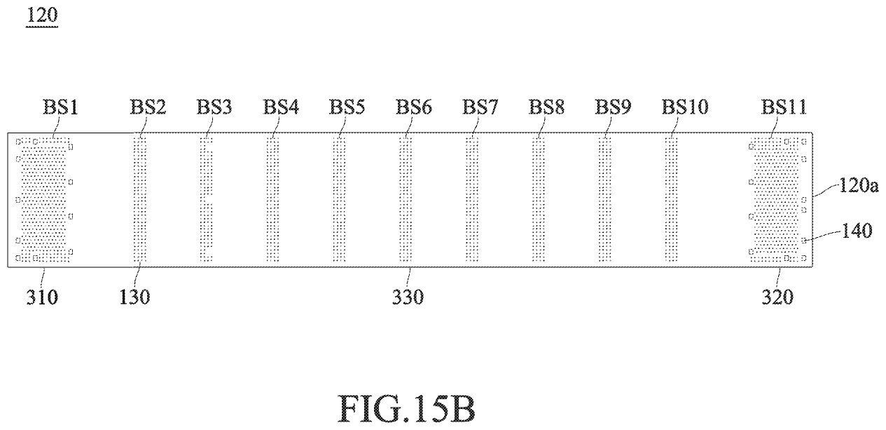

FIG. 14 is a schematic cross-sectional view illustrating a circuit board structure 1400 according to the third exemplary embodiment of the present disclosure. FIG. 15A is a schematic plan view illustrating a first circuit board 110 of the circuit board structure 1400 according to the third exemplary embodiment of the present disclosure. FIG. 15B is a schematic plan view illustrating a second circuit board 120 of the circuit board structure 1400 according to the third exemplary embodiment of the present disclosure. As illustrated in FIGS. 14 and 15A, the circuit board structure 1400 differs from the circuit board structure 100 in that a first set of the spacers 140 (only one of the spacers 140 is labeled in FIG. 15A) of the circuit board structure 1400 are mounted on, i.e., soldered to, e.g., the middle portion 230 of the board layer 110a of the first circuit board 110 of the circuit board structure 1400. With further reference to FIG. 15B, a second set of the spacers 140 (only one of the spacers 140 is labeled in FIG. 15B) of the circuit board structure 1400 are mounted on, i.e., soldered to, the end portions 310, 320 of the film layer 120a of the second circuit board 120 of the circuit board structure 1400. The middle portion 330 of the film layer 120a of the second circuit board 120 of the circuit board structure 1400 is dispensed with spacers.

As such, when the film layer 120a of the second circuit board 120 of the circuit board structure 1400 is mounted on the board layer 110a of the first circuit board 110 of the circuit board structure 1400, the spacers 140 in the first set abut, i.e., not soldered to, the conductive pads, e.g., conductive pads 160 of FIG. 1, the signal lines, e.g., signal lines 120c, the electrical ground, and/or the flexible substrate of the film layer 120a of the second circuit board 120 of the circuit board structure 1400.

The spacers 140 in the second set abut, i.e., not soldered to, the conductive pads, e.g., conductive pads 150 of FIG. 1, the signal lines, e.g., signal lines 110c, the electrical ground, and/or the rigid substrate of the board layer 110a of the first circuit board 110 of the circuit board structure 1400.

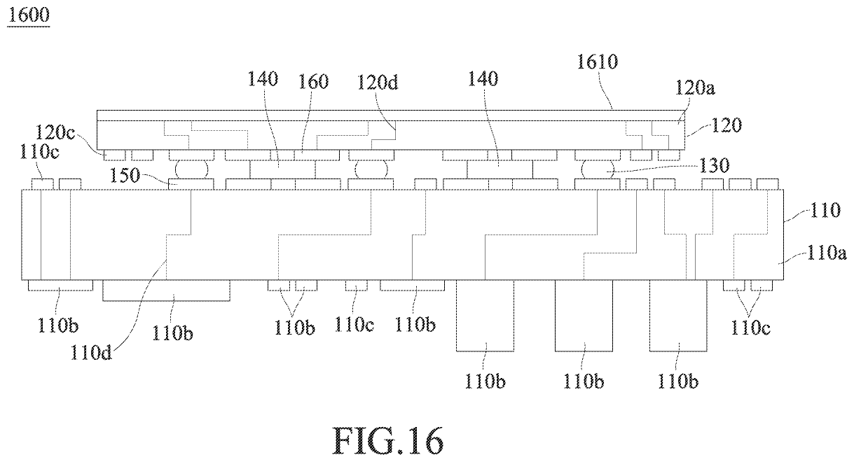

FIG. 16 is a schematic cross-sectional view illustrating a circuit board structure 1600 according to the fourth exemplary embodiment of the present disclosure. The circuit board structure 1600 differs from the previous embodiments in that the circuit board structure 1600 further includes a carrier 1610, e.g., a stiffener, attached to the front of the film layer 120a of the second circuit board 120 of the circuit board structure 1600. The carrier 1610 is configured to stiffen the film layer 120a of the second circuit board 120 of the circuit board structure 1600. The construction as such facilitates fabrication of the second circuit board 120 of the circuit board structure 1600. Examples of materials for the carrier 1610 include, but are not limited to, polyimide, aluminum, and stainless steel. For example, the carrier 1610 has a thickness from about 10 um to about 100 um.

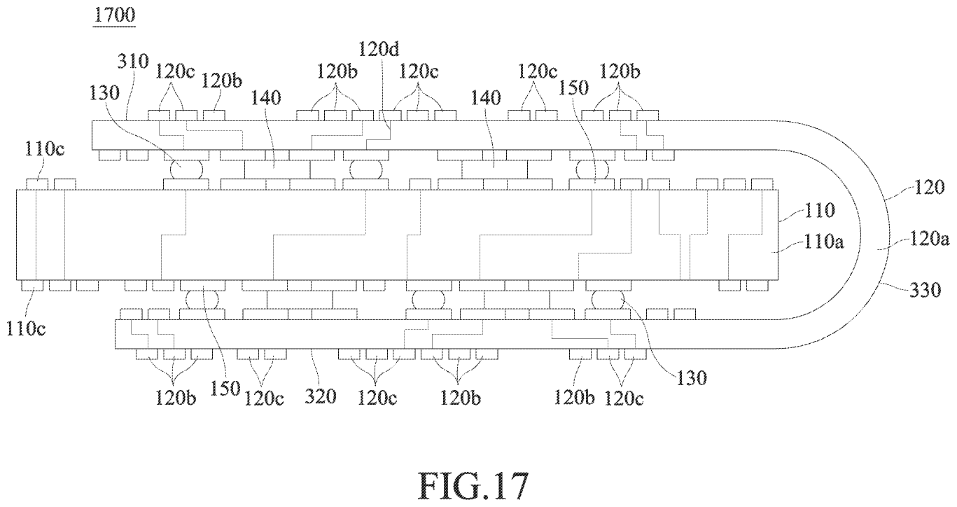

Although the circuit board structures 100, 1200, 1400, 1600 are exemplified with the end portions 310, 320 of the second circuit board 120 connected to the back of the first circuit board 110, it should be understood that, after reading this disclosure, the second circuit board 120 may partially overlaps the first circuit board 110. For example, FIG. 17 is a schematic cross-sectional view illustrating a circuit board structure 1700 according to the fifth exemplary embodiment of the present disclosure. The circuit board structure 1700 differs from the previous embodiments in that the conductive bumps 130 at the end portions 310, 320 of the second circuit board 120 of the circuit board structures 1700 are connected to the conductive pads 150 on the front and back of the first circuit board 110 of the circuit board structure 1700, respectively.

The spacers 140 at the end portions 310, 320 of the second circuit board 120 of the circuit board structure 1700 are mounted to, i.e., soldered to, one of the first and second circuit boards 110, 120 and abut, i.e., not soldered to, the other of the first and second circuit boards 110, 120.

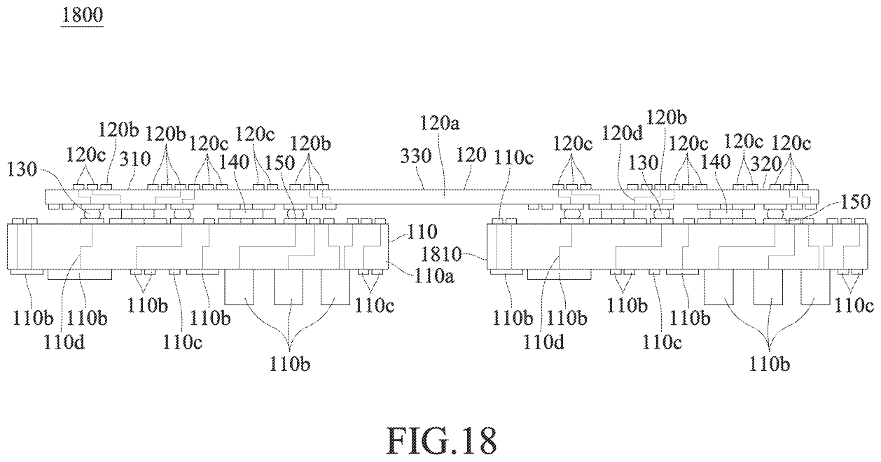

FIG. 18 is a schematic cross-sectional view illustrating a circuit board structure 1800 according to the sixth exemplary embodiment of the present disclosure. The circuit board structure 1800 differs from the previous embodiments in that that the conductive bumps 130 at the end portions 310, 320 of the second circuit board 120 of the circuit board structure 1800 are connected to the conductive pads 150 of the first circuit board 110 of the circuit board structure 1800 and conductive pads 150 of a third circuit board 1810 of the circuit board structure 1800, respectively.

The spacers 140 at the end portion 310 of the second circuit board 120 of the circuit board structure 1800 are mounted to, i.e., soldered to, one of the first and second circuit boards 110, 120 and abut, i.e., not soldered to, the other of the first and second circuit boards 110, 120.

The spacers 140 at the end portion 320 of the second circuit board 120 of the circuit board structure 1800 are mounted to, i.e., soldered to, one of the first and third circuit boards 110, 1810 of the circuit board structure 1800 and abut, i.e., are not soldered to, the other of the first and third circuit boards 110, 1810 of the circuit board structure 1800.

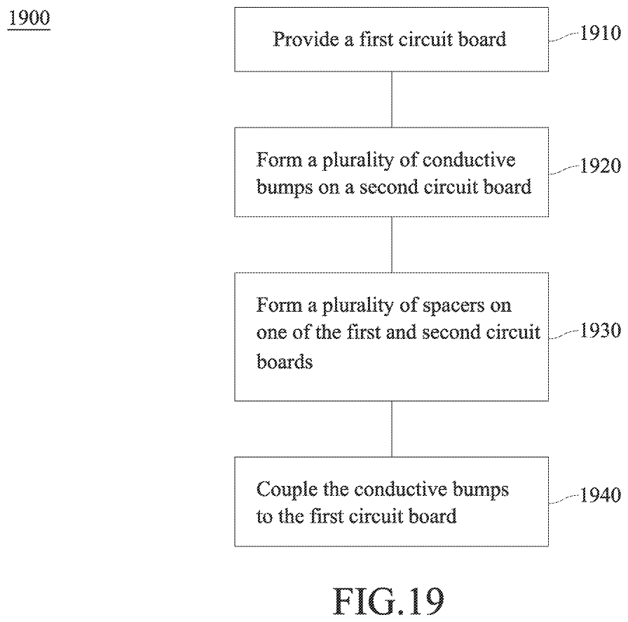

FIG. 19 is a flowchart illustrating a method 1900 of manufacturing a circuit board structure, e.g., circuit board structure 100 of FIG. 1, according to some embodiments of the present disclosure. The method 1900 begins with operation 1910, where a first circuit board, e.g., first circuit board 110, is provided. At operation 1920, a plurality of conductive bumps, e.g., conductive bumps 130, are formed on a second circuit board, e.g., second circuit board 120. At operation 1930, a plurality of spacers, e.g., spacers 140, are formed on one of the first and second circuit boards 110, 120. At operation 1940, the conductive bumps 130 are coupled to the first circuit board 110 such that the spacers 140 abut the other of the first and second circuit boards 110, 120.

In an embodiment, the present disclosure discloses a circuit board structure. The circuit board structure comprises a rigid circuit board, a flexible circuit board, a plurality of conductive bumps, and a plurality of spacers. The rigid and flexible circuit boards are stacked one above the other. The conductive bumps are formed between the rigid and flexible circuit boards. The spacers are formed between the rigid and flexible circuit boards and spaced apart from the conductive bumps.

In another embodiment, the present disclosure discloses a circuit board structure. The circuit board structure comprises a first flexible circuit board, a second flexible circuit board, and a plurality of conductive bumps. The first and second flexible circuit boards are stacked one above the other. The conductive bumps are formed between the first and second flexible circuit boards.

In another embodiment, the present disclosure discloses a method of fabricating a circuit board structure. The method comprises providing a first circuit board, forming a plurality of conductive bumps on a second circuit board, after forming the conductive bumps, forming a plurality of spacers on one of the first and second circuit boards, and coupling the conductive bumps to the first circuit board such that the spacers abut the other of the first and second circuit boards.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure comprising:
a rigid circuit board;
a flexible circuit board, wherein the rigid and flexible circuit boards are stacked one above the other;
a plurality of conductive bumps formed between the rigid and flexible circuit boards; and
a plurality of spacers formed between the rigid and flexible circuit boards and spaced apart from the conductive bumps.

2. The circuit board structure of claim 1, wherein the spacers are mounted on one of the rigid and flexible circuit boards and abutting the other of the rigid and flexible circuit boards.

3. The circuit board structure of claim 1, wherein one or more of the spacers are a surface mount device (SMD).

4. The circuit board structure of claim 1, wherein the spacers are mounted on signal lines of the flexible circuit board.

5. The circuit board structure of claim 1, wherein the spacers are mounted on an electrical ground of the flexible circuit board.

6. The circuit board structure of claim 1, wherein three or more of the spacers are adjacent a corner of the flexible circuit board.

7. The circuit board structure of claim 1, wherein the spacers are arranged in an array of rows and columns.

8. The circuit board structure of claim 1, wherein the conductive bumps define a bump area and the spacers surround the bump area.

9. The circuit board structure of claim 1, wherein the conductive bumps define a bump area and the spacers are in the bump area.

10. The circuit board structure of claim 1, further comprising a carrier attached to and configured to stiffen the flexible circuit board.

11. A circuit board structure comprising:
a first flexible circuit board;
a second flexible circuit board, wherein the first and second flexible circuit boards are stacked one above the other; and
a plurality of conductive bumps formed between the first and second flexible circuit boards.

12. The circuit board structure of claim 11, further comprising a plurality of spacers formed between the first and second flexible circuit boards and spaced apart from the conductive bumps.

13. The circuit board structure of claim 12, wherein the spacers are mounted on one of the first and second flexible circuit boards and abutting the other of the first and second flexible circuit boards.

14. The circuit board structure of claim 12, wherein one or more of the spacers are a surface mount device (SMD).

15. A method of fabricating a circuit board structure, the method comprising:
providing a first circuit board;
forming a plurality of conductive bumps on a second circuit board;
after forming the conductive bumps, forming a plurality of spacers on one of the first and second circuit boards; and
coupling the conductive bumps to the first circuit board such that the spacers abut the other of the first and second circuit boards.

16. The method of claim 15, wherein coupling the conductive bumps includes mounting the second circuit board on the first circuit board using surface mount technology (SMT).

17. The method of claim 15, wherein forming the spacers includes mounting the spacers on one of the first and second circuit boards using SMT.

18. The method of claim 15, further comprising pressing the first and second circuit boards against each other.

19. The method of claim 15, further comprising performing a reflow soldering process on the first and second circuit boards.

20. The method of claim 15, wherein the second circuit board is a flexible circuit board.
